(19) United States
(12) Patent Application Publication
(10) Pub. No.: US 2015/0136017 A1
(43) Pub. Date: May 21, 2015

(54) CARBON CRUCIBLE AND METHOD OF MANUFACTURING SAME

(71) Applicant: TOYO TANSO CO., LTD., Osaka-shi, Osaka (JP)

(72) Inventors: Toshiharu Hiraoka, Mitoyo-shi (JP); Hiroshi Machino, Mitoyo-shi (JP); Masaaki Kawakami, Mitoyo-shi (JP)

(73) Assignee: TOYO TANSO CO., LTD., Osaka-shi, Osaka (JP)

(21) Appl. No.: 14/411,182

(22) PCT Filed: Jul. 1, 2013
(86) PCT No.: PCT/JP2013/067991

§ 371 Date: Dec. 24, 2014

(30) Foreign Application Priority Data
Jul. 4, 2012 (JP) 2012-150357

(51) Int. Cl. C30B 15/10; C30B 35/00

(52) U.S. Cl. CPC C30B 15/10; C30B 35/002
USPC 117/208; 29/428

(57) ABSTRACT

A carbon crucible (1) has a structure including a straight trunk portion (9) and a tray portion (10) vertically separated from each other. The straight trunk portion (9) is made of a carbon fiber-reinforced carbon composite material and the tray portion (10) is made of graphite. An upper end face of the tray portion (9) is provided with a step portion (11) having an outer circumference-side region that is higher relative to an inner circumference-side region thereof. The straight trunk portion (9) is fitted to the step portion (11), and in the straight trunk portion (9) and the step portion (9) that are fitted to each other, a gap is provided between an inner circumferential surface (11a) of the step portion (11) and an outer circumferential surface (9a) of the straight trunk portion (9). The gap is preferably from 0.1% to 1.0% of the diameter of the straight trunk portion.

### TECHNICAL FIELD

The present invention relates to a carbon crucible for retaining a quartz crucible used in a metal single crystal pulling apparatus for silicon or the like, and a method of manufacturing the same.

### BACKGROUND ART

A crucible used for the Czochralski process (hereinafter referred to as the “CZ process”) has a double structure including a quartz crucible for melting silicon and a graphite crucible for accommodating the quartz crucible. In recent years, large-sized single crystals tend to have been produced in order to obtain silicon single crystals at high yield rates. Correspondingly, large-sized graphite crucibles have become necessary. However, as the capacity of the graphite crucible increases, the heat warpage resulting from the difference in thermal expansion rate between the quartz crucible and the graphite crucible accordingly increases in size. Consequently, stress concentration occurs in the straight trunk portion, especially in the upper edge portion thereof and in the curved surface portion (hereinafter may be referred to as a “curved portion”) that is connected from the bottom portion to the straight trunk portion, so that cracks are likely to occur in the graphite crucible. In order to resolve this problem, some proposals have been made, such as a composite crucible in which the straight trunk portion and the tray portion are separated, the straight trunk portion using a carbon fiber-reinforced carbon composite material (C/C composite material) and the tray portion using a graphite material (see Patent Literature 1 listed below) and a composite crucible in which the straight trunk portion uses a thin-type carbon fiber-reinforced carbon composite material (see Patent Literature 2 listed below).

### CITATION LIST

### Patent Literature

[Patent Literature 1]

Japanese Examined Utility Model Publication No. H03(1991)-043250

[Patent Literature 2]

JP H08(1996)-073292 A

### SUMMARY OF INVENTION

### Technical Problem

However, in the crucible disclosed in Patent Literature 1 above, the straight trunk portion and the tray portion are fixed by providing respective steps in the straight trunk portion and the tray portion and making them engage with each other. Accordingly, in such cases that the roundness of the straight trunk portion is not exactly as designed but has some dimensional errors, or that the straight trunk portion causes deformation during shipping from the site of production to the site of assembling, the steps of the straight trunk portion and the tray portion are difficult to engage with each other as they are, and therefore, the need arises to correct the warpage in the straight trunk portion. If it is desired to solve such a problem, high-precision processing becomes necessary to increase the roundness of the straight trunk portion, which increases the cost. Moreover, since the warpage correction for the straight trunk portion must be carried out with high precision, a considerable amount of labor needs to exerted for the warpage correction, resulting in a longer delivery time.

Although the crucible disclosed in the above-mentioned Patent Literature 2 uses a thin-type carbon fiber-reinforced carbon composite material for the straight trunk portion, the design of the hollow cylindrical portion does not take dimensional accuracy into consideration. Therefore, it also has the problem that the straight trunk portion and the tray portion may not be fixed because of the deformation or the like in the straight trunk portion, as in the case of the crucible disclosed in the above-mentioned Patent Literature 1. Moreover, it requires a ring-shaped spacer in order to retain the hollow cylindrical portion (i.e., the straight trunk portion) from the inside. Therefore, the crucible disclosed in Patent Literature 2 also has the problem of high cost and long delivery time.

Accordingly, there has long been a demand for a carbon crucible that has a structure in which the straight trunk portion and the tray portion are separated in order to prevent cracks in the crucible, and that is moreover low in cost and makes a short delivery time possible, and a method of manufacturing the carbon crucible.

The present invention has been accomplished in view of the foregoing circumstances. It is an object of the invention to provide a carbon crucible that has a structure in which the straight trunk portion and the tray portion are separated in order to prevent cracks in the crucible, and that is moreover low in cost and makes a short delivery time possible, and a method of manufacturing the same.

### Solution to Problem

In order to accomplish the foregoing object, the present invention provides a carbon crucible comprising a straight trunk portion and a tray portion vertically separated from each other, wherein: an upper end face of the tray portion that is in contact with the straight trunk portion is provided with a step portion having an inner circumference-side region and an outer circumference-side region, one of which being higher relative to the other; and the straight trunk portion is fitted to the step portion, and a gap is provided between the step portion and the straight trunk portion that are fitted to each other.

With the above-described configuration, even when the dimensions are not exactly as designed because of a problem in the roundness of the straight trunk portion in assembling the straight trunk portion and the tray portion together at a customer's site, smooth fitting can be achieved because the gap serves as a clearance. In addition, the straight trunk portion may cause deformation during transport. Even in such a case, because the gap serves as a clearance, the fitting can be performed while the labor for correcting warpage or the like can be minimized. As a result, a short delivery time becomes possible. Moreover, it becomes unnecessary to use a member that has been necessary in conventional examples such as a ring-shaped spacer for retaining the hollow cylindrical portion (i.e., the straight trunk portion) from the inside. As a result, a low cost can be achieved.

In the present invention, it is preferable that the upper end face that is in contact with the straight trunk portion be provided with a step portion having the outer circumference-side region that is higher than the inner circumference-side region thereof. The straight trunk portion is fitted to the step portion, and in the straight trunk portion and the step portion that are fitted to each other, a gap is provided between an inner circumferential surface of the step portion and an outer circumferential surface of the straight trunk portion. With such a configuration, the straight trunk portion is allowed to exist at a position closer to the quartz crucible. Therefore, it becomes possible to quickly respond to the deformation of the quartz crucible when retaining the quartz crucible.

In the present invention, it is preferable that the step portion comprise at least a plurality of step portions provided along a circumferential direction. The processing time can be shortened in comparison with the configuration in which the step portion is provided along the entire circumference.

In the present invention, it is preferable that the step portion be provided along the entire circumference. With such a configuration, the stability of the straight trunk portion fitted to the tray portion is improved further.

In the present invention, it is preferable that the straight trunk portion be made of a carbon fiber-reinforced carbon composite material. Such a configuration has the advantages that it is easy to form a cylindrical shape, and that cracks and chipping are unlikely to occur during storage and during processing.

In the present invention, it is preferable that the size of the gap be from 0.1% to 1.0% of the diameter of the straight trunk portion. The reason for such restriction is as follows. If the value is less than 0.1%, smooth fitting becomes difficult. If the value exceeds 1.0%, such problems arise that wobbling occurs between the straight trunk portion and the tray and that it becomes necessary to design the step portion to be larger than necessary. It has been confirmed by an experiment that, within the just-mentioned range of 0.1% to 1.0%, the fitting can be achieved properly.

The present invention also provides a method of manufacturing a carbon crucible including a straight trunk portion and a tray portion vertically separated from each other, the method comprising: a first step of preparing a hollow cylindrical-shaped product for producing a straight trunk portion and a graphite block for producing a tray portion; a second step of cutting the hollow cylindrical-shaped product into a desired length to produce the straight trunk portion, and processing the graphite block into the tray portion; and a third step of assembling the straight trunk portion and the tray portion together at a destination site.

With such a configuration, a carbon crucible that meets customer requests can be manufactured quickly and easily merely by cutting the hollow cylindrical-shaped product into a desired length to form the straight trunk portion and subjecting the tray portion to a cutting process. Moreover, the portion that needs to be removed from the raw material by a cutting process becomes less in the tray portion, not just in the straight trunk portion. As a result, the raw material can be used efficiently.

In the present invention, it is preferable that the straight trunk portion be made of a carbon fiber-reinforced carbon composite material. Such a configuration has the advantages that it is easy to form a cylindrical shape, and that cracks and chipping are unlikely to occur during storage and during processing.

In the present invention, it is preferable that the graphite block be a cylindrical-shaped product having a predetermined size that has been determined in advance so as to correspond to the straight trunk portion. With such a configuration, it becomes unnecessary to process the outer circumference portion of the graphite block, so an even shorter delivery time becomes possible.

In the present invention, it is preferable that the hollow cylindrical-shaped product comprise a plurality of types of hollow cylindrical-shaped products prepared so as to suit the size of the crucible. With such a configuration, a carbon crucible that meets customer requests can be manufactured quickly and easily.

### Advantageous Effects of Invention

According to the present invention, even when the dimensions are not exactly as designed because of a problem in the roundness of the straight trunk portion in assembling the straight trunk portion and the tray portion together at a customer's site, smooth fitting can be achieved because the gap serves as a clearance. In addition, the straight trunk portion may cause deformation during transport. Even in such a case, because the gap serves as a clearance, the fitting can be performed while the labor for correcting warpage or the like can be minimized. As a result, a short delivery time becomes possible. Moreover, it becomes unnecessary to use a member that has been necessary in conventional examples such as a ring-shaped spacer for retaining the hollow cylindrical portion (i.e., the straight trunk portion) from the inside. As a result, a low cost can be achieved.

### BRIEF DESCRIPTION OF DRAWINGS

FIG. 1 is a cross-sectional view illustrating a primary portion of a silicon single crystal pulling apparatus equipped with a carbon crucible according to the present invention.

FIG. 2 is a perspective view of the carbon crucible according to the present invention.

FIG. 3 is a front view of the carbon crucible according to the present invention.

FIG. 4 is a vertical cross-sectional view of the carbon crucible according to the present invention.

FIG. 5 is a cross-sectional view illustrating a portion of FIG. 4 enlarged.

FIG. 6 is a view for illustrating a method of manufacturing a carbon crucible.

FIG. 7 is a cross-sectional view of a modified example of the carbon crucible.

### DESCRIPTION OF EMBODIMENTS

Hereinbelow, the present invention will be described based on the preferred embodiments. It should be noted that the present invention is not limited to the following embodiments.

### Embodiment 1

Hereinbelow, the present invention will be described based on the preferred embodiments. It should be noted that the present invention is not limited to the following embodiments.

(Configuration of Metal Single Crystal Pulling Apparatus)

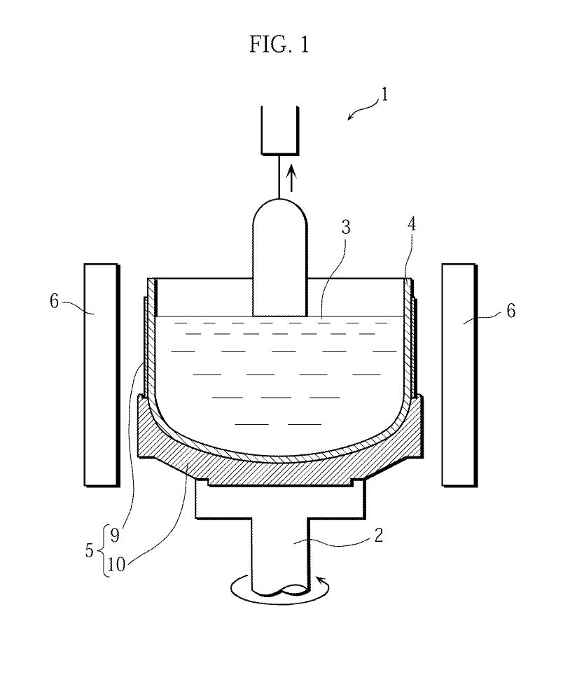

FIG. 1 is a cross-sectional view illustrating a primary portion of a silicon single crystal pulling apparatus equipped with a carbon crucible according to the present invention. In FIG. 1, reference numeral 1 denotes a single crystal pulling apparatus, reference numeral 2 denotes a shaft, reference numeral 4 denotes a quartz crucible for accommodating silicon melt 3, and reference numeral 5 denotes a carbon crucible for retaining the quartz crucible 4. A heater 6 is disposed around the outer periphery of the carbon crucible 5. The silicon melt 3 is heated by the heater 6 through the carbon crucible 5 and the quartz crucible 4, and while pulling up an ingot 7, a silicon single crystal is produced.

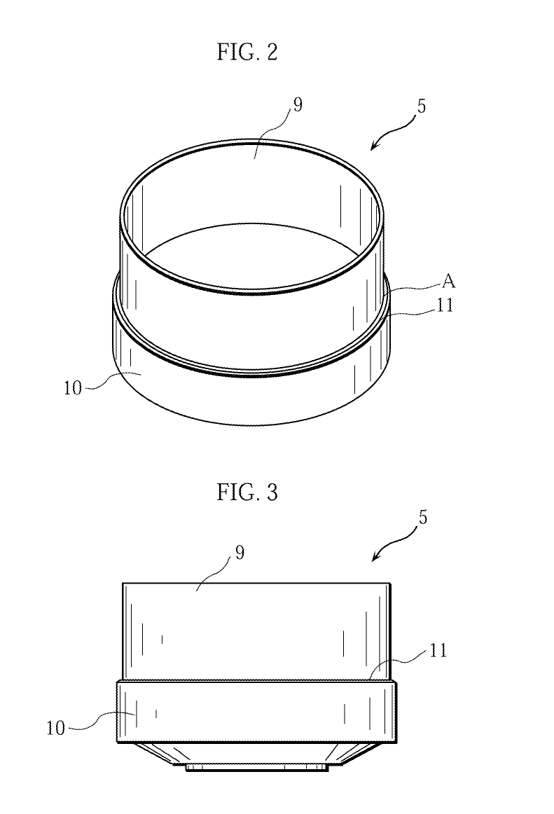

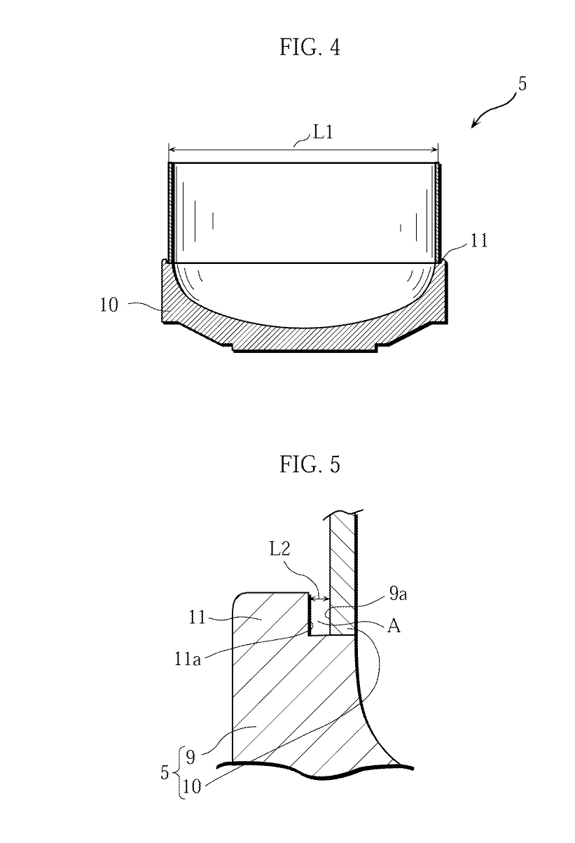

FIG. 2 is a perspective view of the carbon crucible according to the present invention. FIG. 3 is a front view of the carbon crucible according to the present invention. FIG. 4 is a vertical cross-sectional view of the carbon crucible according to the present invention. FIG. 5 is a cross-sectional view illustrating a portion of FIG. 4 enlarged. The carbon crucible 5 has a substantially circular tubular straight trunk portion 9 and a tray portion 10, and the straight trunk portion 9 and the tray portion 10 are separated from each other. The straight trunk portion 9 is made of a carbon fiber-reinforced carbon composite material (C/C composite material), and the tray portion 10 is made of graphite.

An upper end face of the tray portion 10 is provided with a step portion 11 having an outer circumference-side region that is higher relative to an inner circumference-side region thereof. This step portion 11 is provided along the entire circumference, and the straight trunk portion 9 is fitted to the step portion 11. Such a structure in which the straight trunk portion 9 is fitted to the step portion 11 can lower the risk of causing the straight trunk portion 9 from coming off from the tray portion 10 and the risk of causing the straight trunk portion 9 from being dislocated in a horizontal direction.

Here, a gap A is provided between an inner circumferential surface 11a of the step portion 11 and an outer circumferential surface 9a of the straight trunk portion 9 in a condition in which the straight trunk portion 9 is fitted to the step portion 11. This gap A functions as a clearance when assembling the straight trunk portion 9 and the tray portion 10 together. Thereby, it becomes possible to smoothly fit the straight trunk portion 9 and the tray portion 10 to each other when assembling the straight trunk portion 9 and the tray portion 10 together. More specifically, in such cases that the roundness of the straight trunk portion 9 is not exactly as designed but has some dimensional errors, or that the straight trunk portion 9 causes deformation during shipping of the straight trunk portion 9 from the site of production to the site of assembling, the gap A serves as a clearance, and so smooth fitting becomes possible. Moreover, even when the deformation of the straight trunk portion 9 is to be corrected, the correction of the warpage or the like can be carried out with minimum labor when performing the fitting.

Herein, because an appropriate size L2 [mm] (see FIG. 5) of the gap A varies depending on the diameter L1 [mm] (see FIG. 4) of the straight trunk portion 9, it is preferable that the size L2 of the gap A be from 0.1% to 1.0% of the diameter L1 of the straight trunk portion 9. The reason for such restriction of the value is as follows. If the value is less than 0.1%, smooth fitting becomes difficult. If the value exceeds 1.0%, such problems arise that wobbling occurs between the straight trunk portion and the tray and that it becomes necessary to design the step portion 11 to be larger than necessary.

(Method of Manufacturing Carbon Crucible)

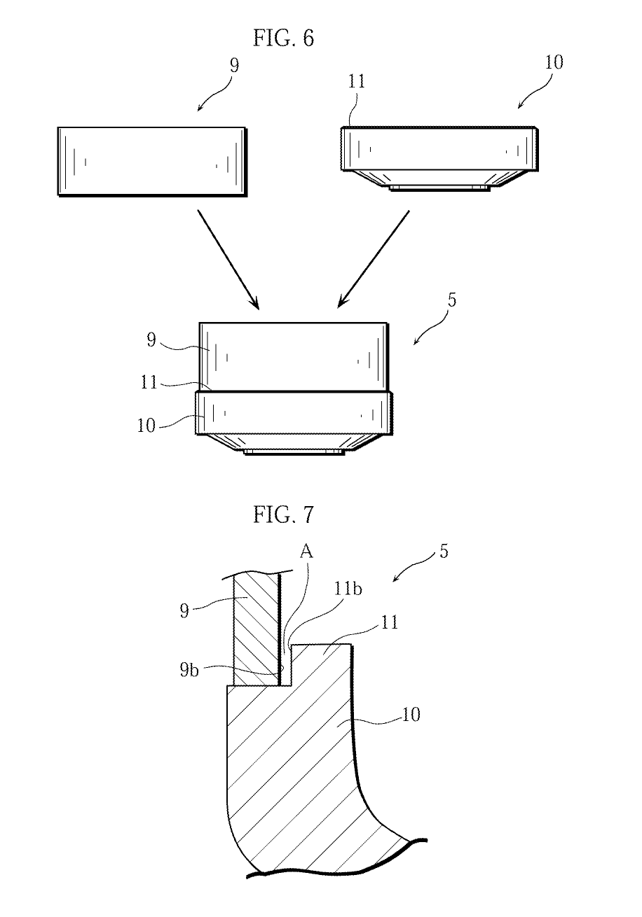

FIG. 6 is a view for illustrating a method of manufacturing a carbon crucible.

The straight trunk portion 9 and the tray portion 10 are manufactured as will be described below. Next, the straight trunk portion 9 and the tray portion 10 are assembled together to form a final shape. It should be noted that, at the stage of designing the straight trunk portion 9 and the tray portion 10, the dimensions of the straight trunk portion 9 and the tray portion 10 are set in advance so that a gap A can be provided between the inner circumferential surface 11a of the step portion 11 and the outer circumferential surface 9a of the straight trunk portion 9 when the straight trunk portion 9 and the tray portion 10 are assembled together.

(1) Production of the Straight Trunk Portion 9

A precursor having a uniform outer diameter and a uniform thickness is prepared by a filament winding method, and the resultant precursor is sintered to form a C/C composite, to thereby obtain a hollow cylindrical-shaped product. Since the hollow cylindrical-shaped product has a uniform outer diameter and a uniform thickness, a uniform straight trunk portion 9 can be obtained even when any location thereof is cut out to meet the customer request. Therefore, the delivery time can be shortened.

Next, as illustrated in FIG. 6, the hollow cylindrical-shaped product is cut to obtain an uniform straight trunk portion 9 that meets a customer request.

It is preferable that a plurality of types of hollow cylindrical-shaped products with a plurality of kinds of diameters be prepared to suit the size of the crucible. The reason is that it is possible to obtain the straight trunk portion 9 that meets the customer request quickly.

(2) Production of Tray Portion 10

A graphite block is roughly cut into a size according to the dimensions of the tray portion, and the cut-out portion is subjected to a finishing process, to form a tray portion 10 as shown in FIG. 6. The reason why the graphite block is used to produce the tray portion 10 is that waste of the raw material can be lessened by processing it from a block shape because the shape of the tray portion 10 may be different depending on the customer.

It is preferable that the graphite block be a block in a cylindrical shape and that a plurality of types of graphite blocks having a plurality of kinds of outer circumference sizes corresponding to the size of the straight trunk portion 9 be prepared. Because it becomes unnecessary to process the outer circumference portion of the graphite block and the rough processing finishes only by the cutting in a cross-sectional direction, the delivery time can be shortened.

In addition, it is preferable that the material be processed into such a shape that its center is depressed in the rough processing. The reason is that the raw material can be processed efficiently in that way.

(3) Production of Crucible

The straight trunk portion 9 produced in the above-described manner and the tray portion 10 produced in the above-described manner are separately packed and transported to a customer's site, and are assembled together at the customer's site, to fabricate a carbon crucible 5 in a final shape as shown in FIG. 6. Since the gap A is designed in advance to exist when assembling the parts together into the final shape at a customer's site, smooth fitting is made possible.

### Other Embodiments

(1) In the foregoing embodiment, the step portion 11 is provided along the entire circumference. However, it is possible to employ the configuration in which a plurality of step portions are provided so as to be spaced apart from each other along the circumferential direction. In this case, it is preferable that the plurality of step portions 11 be provided at regular intervals along the circumferential direction. The reason is because the stability of the straight trunk portion 9 fitted to the tray portion 10 is improved.

(2) In the foregoing embodiment, the upper end face of the tray portion 10 is provided with the step portion 11 the outer circumference-side region of which is higher relative to the inner circumference-side region thereof. The straight trunk portion 9 is fitted to the step portion 11, and in the straight trunk portion 9 and the step portion 11 that are fitted to each other, the gap A is provided between the inner circumferential surface 11a of the step portion 11 and the outer circumferential surface 9a of the straight trunk portion 9. However, the present invention is not limited thereto. The configuration as illustrated in FIG. 7 is also possible. Specifically, the upper end face of the tray portion 10 may be provided with a step portion 11 the inner circumference-side region of which is higher relative to the outer circumference-side region thereof. The straight trunk portion 9 may be fitted to the step portion 11, and in the straight trunk portion 9 and the step portion 11 that are fitted to each other, a gap A may be provided between an outer circumferential surface 11b of the step portion 11 and an inner circumferential surface 9b of the straight trunk portion 9.

### Examples

Four types of carbon crucibles (Example 1, Example 2, Example 3, and Example 4) having various sizes L2 of the gap A and various diameters L1 of the straight trunk portion were manufactured in the same manufacturing method as described in the foregoing embodiment, to investigate the degree of fitting. The results are shown in Table 1. In addition, the degree of fitting was also investigated for three types of carbon crucibles (Comparative Example 1, Comparative Example 2, and Comparative Example 3) that were manufactured in the same manufacturing method as described in the foregoing embodiment, except that the proportion of the size L2 of the gap A to the diameter L1 of the straight trunk portion was outside the range of from 0.1% to 1.0%. The results are also shown in Table 1.

TABLE 1

| | Diameter L1 | | Proportion | |
|---|---|---|---|---|
| | of straight | Size L2 | of gap | |
| | trunk portion | of gap A | (L2/L1 × 100) | Degree of |
| | [mm] | [mm] | [%] | fitting |
| Ex. 1 | 600 | 1.0 | 0.16 | Smooth and |
| | | | | adequate |
| Ex. 2 | 700 | 1.5 | 0.21 | Smooth and |
| | | | | adequate |
| Ex. 3 | 800 | 1.5 | 0.19 | Smooth and |
| | | | | adequate |
| Ex. 4 | 600 | 5.0 | 0.83 | Smooth and |
| | | | | adequate |
| Comp. | 600 | 0.5 | 0.08 | Involved |
| Ex. 1 | | | | considerable |
| | | | | difficulty |
| Comp. | 600 | 0.3 | 0.05 | Unable to fit |
| Ex. 2 | | | | together |
| Comp. | 600 | 6.0 | 1.00 | Partially falls |
| Ex. 3 | | | | inside, large |
| | | | | wobbling -- |
| | | | | Unacceptable |

As clearly seen from Table 1, smooth and adequate fitting was obtained with all the Examples 1 to 4, in which the proportion of the size L2 of the gap A to the diameter L1 of the straight trunk portion was in the range of from 0.1% to 1.0%. In contrast, as for Comparative Examples 1 and 2, in which the proportion of the size L2 of the gap A to the diameter L1 of the straight trunk portion is outside the range of from 0.1% to 1.0%, Comparative Example 1 involved considerable difficulty in fitting, and Comparative Example 2 was unable to fit together. Comparative Example 3, in which the proportion of the size L2 of the gap A to the diameter L1 of the straight trunk portion exceeded 1.0%, had a portion that fell inside partially, showed large wobbling; thus, it was unacceptable. From the above, it will be appreciated that it is preferable that the size L2 of the gap A be from 0.1% to 1.0% of the diameter L1 of the straight trunk portion 9.

### INDUSTRIAL APPLICABILITY

The present invention is applicable to a carbon crucible for retaining a quartz crucible used in a metal single crystal pulling apparatus for silicon or the like, and to a method of manufacturing the same.

### REFERENCE SIGNS LIST

1—Single crystal pulling apparatus
4—Quartz crucible
5—Carbon crucible
9—Straight trunk portion
9a—Outer circumferential surface of the straight trunk portion 9
10—Tray portion
11—Step portion
11a—Inner circumferential surface of the step portion 11
A—Gap A

1. A carbon crucible comprising a straight trunk portion and a tray portion vertically separated from each other, characterized in that:
an upper end face of the tray portion that is in contact with the straight trunk portion is provided with a step portion having an inner circumference-side region and an outer circumference-side region, one of which being higher relative to the other; and
the straight trunk portion is fitted to the step portion, and a gap is provided between the step portion and the straight trunk portion that are fitted to each other.

2. The carbon crucible according to claim 1, wherein:
the upper end face of the tray portion that is in contact with the straight trunk portion is provided with a step portion having the outer circumference-side region that is higher relative to the inner circumference-side region; and
the straight trunk portion is fitted to the step portion, and in the straight trunk portion and the step portion that are fitted to each other, a gap is provided between an inner circumferential surface of the step portion and an outer circumferential surface of the straight trunk portion.

3. The carbon crucible according to claim 1, wherein the step portion comprises at least a plurality of step portions provided along a circumferential direction.

4. The carbon crucible according to claim 1, wherein the step portion is provided along an entire circumference.

5. The carbon crucible according to claim 1, wherein the straight trunk portion is made of a carbon fiber-reinforced carbon composite material.

6. The carbon crucible according to claim 1, wherein the size of the gap is from 0.1% to 1.0% of the diameter of the straight trunk portion.

7. A method of manufacturing a carbon crucible including a straight trunk portion and a tray portion vertically separated from each other, the method comprising:
a first step of preparing a hollow cylindrical-shaped product for producing a straight trunk portion and a graphite block for producing a tray portion;
a second step of cutting the hollow cylindrical-shaped product into a desired length to produce the straight trunk portion, and processing the graphite block into the tray portion; and
a third step of assembling the straight trunk portion and the tray portion together at a destination site.

8. The method of manufacturing a carbon crucible according to claim 7, wherein the straight trunk portion is made of a carbon fiber-reinforced carbon composite material.

9. The method of manufacturing a carbon crucible according to claim 7, wherein the graphite block is a cylindrical-shaped product having a predetermined size that has been determined in advance so as to correspond to the straight trunk portion.

10. The carbon crucible according to claim 7, wherein the hollow cylindrical-shaped product comprises a plurality of types of hollow cylindrical-shaped products prepared so as to suit the size of the crucible.
